(19) United States
(12) Patent Application Publication
(10) Pub. No.: US 2022/0278662 A1
(43) Pub. Date: Sep. 1, 2022

(54) Operational Amplifier

(71) Applicant: Mitsubishi Electric Corporation, Chiyoda-ku, Tokyo (JP)

(72) Inventor: Tomokazu KOJIMA, Chiyoda-ku, Tokyo (JP)

(73) Assignee: Mitsubishi Electric Corporation, Chiyoda-ku, Tokyo (JP)

(21) Appl. No.: 17/631,625

(22) PCT Filed: Oct. 8, 2019
(86) PCT No.: PCT/JP2019/039649

§ 371 Date: Jan. 31, 2022

(51) Int. Cl. H03F 3/45

(52) U.S. Cl. CPC H03F 3/45269; H03F 3/45183; H03F 2203/45244

(57) ABSTRACT

An operational amplifier operates in the entire voltage range of supplied first and second voltages as an input and output range. An active load is formed with a field-effect transistor of a first conductivity type. First and second differential pairs are formed with a field-effect transistor of a second conductivity type. The first differential pair is configured such that differential amplification is possible when an input voltage is the second voltage, and the second differential pair is configured such that differential amplification is possible when the input voltage is the first voltage. A selection circuit selectively connects one of the first and second differential pairs to the active load through a differential node in accordance with the input voltage.

### TECHNICAL FIELD

The present disclosure relates to an operational amplifier.

### BACKGROUND ART

With recent advancement in the Internet of things (IoT) technologies, there has been a growing demand for technologies, including accurate sensors and sensor interfaces. Specifically, there is a need for system technology that connects people and things using information detected by sensors, by accurately receiving information from sensor devices by an operational amplifier (or a comparator) at an input stage and performing analog signal processing or digital signal processing.

One of effective approaches to reduce power consumption in sensors and sensor interfaces is to lower the power supply voltage of sensors. In analog circuits, however, if the power supply voltage is simply lowered, the amplification ratio is reduced or the voltage amplitude of an output signal is reduced. In this respect, full-swing operational amplifiers capable of amplifying the entire power supply voltage range, that is, rail-to-rail (registered trademark) operational amplifiers have been used. In operational amplifiers with rail-to-rail input and output, the power supply voltage range is fully utilized to achieve both less power consumption and high-quality signal amplification.

Unfortunately, in rail-to-rail operational amplifiers, it is usually difficult to ensure the amplification ratio in a low potential region in which an input voltage level is close to the ground or in a high potential region in which an input voltage is close to the power supply voltage.

In order to address this problem, for example, Japanese Patent Laying-Open No. 2009-302619 (PTL 1) describes an operational amplifier in which a first differential pair composed of a depletion-type (D-type) PMOS (metal oxide semiconductor) transistors and a second differential pair composed of enhancement-type (E-type) PMOS transistors are arranged in parallel.

In the operational amplifier described in PTL 1, an input voltage is amplified by the first differential pair in a low potential region, and an input voltage is amplified by the second differential pair in a high potential region, whereby the amplification degree can be ensured in the entire range from ground to power supply voltage.

Further, according to PTL 1, the transconductance (gmdp) in the saturation region of the D-type PMOSFET forming the first differential pair and the transconductance (gmp) in the saturation region of the E-type PMOS forming the second differential pair are designed to be equal, so that the total transconductance (gm) in the operational amplifier is constant between the low potential region and the high potential region.

### CITATION LIST

### Patent Literature

PTL 1: Japanese Patent Laying-Open No. 2009-302619

### SUMMARY OF INVENTION

### Technical Problem

In PTL 1, a PMOS transistor receiving a constant bias voltage (V1) at its gate turns on and off in accordance with the level of the input voltage to allow bias current from a constant current source to be distributed between the first and second differential pairs. Specifically, in the low potential region, the PMOS transistor turns off to distribute all the amount of bias current to the second differential pair (E-type PMOS). On the other hand, in the high potential region, the PMOS transistor turns on to distribute all the amount of bypass current to the first differential pair (D-type PMOS).

However, in the operational amplifier of PTL 1, in an intermediate potential region in which the input voltage is in the vicinity of the bias voltage (V1), both of the first differential pair and the second differential pair operate, so that the total transconductance of the operational amplifier is the mean square of conductance of the first differential pair or the second differential pair. In this case, in the intermediate region, the bias current is distributed between the first and second differential pairs, and the ratio of distribution changes with the input voltage. On the other hand, the conductance of each differential pair changes with current passing through the differential pair.

Therefore, the transconductance of each of the first and second differential pairs in the intermediate region changes from the transconductance matched between the low potential region and the high potential region in which all the amount of bias current flows through only one of the first differential pair and the second differential pair. As a result, it is difficult to make the amplification degree constant for the entire region of the input voltage.

The present disclosure is made in order to solve such a problem, and an object of the present disclosure is to make the amplification degree constant in the entire voltage range in an operational amplifier supplied with first and second voltages and operating in the entire voltage range from the first voltage to the second voltage as the input/output range.

### Solution to Problem

According to an aspect of the present disclosure, an operational amplifier supplied with a first voltage and a second voltage to operate includes first and second input nodes to receive an input voltage, an output node to output an output voltage, first and second differential nodes, an active load, a first differential pair, a second differential pair, an input voltage detection circuit, an output stage, and a selection circuit. The active load is connected between a first power supply node to supply the first voltage and the first and second differential nodes and formed with a field-effect transistor of a first conductivity type. The first differential pair is connected between the first and second differential nodes and a second power supply node to supply the second voltage and formed with a field-effect transistor of a second conductivity type. The second differential pair is connected between the first and second differential nodes and the second power supply node in parallel with the first differential pair and formed with a field-effect transistor of the second conductivity type. Each of the first and second differential pairs produces a current difference between the first and second differential nodes in accordance with a voltage difference between the first and second input nodes. The input voltage detection circuit generates a detection signal for selecting one of the first and second differential pairs in accordance with the input voltage. The output stage changes a voltage at the output node in a range from the first voltage to the second voltage in accordance with a current difference between the first and second differential nodes. The selection circuit electrically connects one of the first and second differential pairs to the first and second differential nodes and electrically cuts off the other from the first and second differential nodes, in accordance with the detection signal. When the first conductivity type is P type and the second conductivity type is N type, the field-effect transistor forming the first differential pair has a threshold voltage equal to or lower than zero and the field-effect transistor forming the second differential pair has a threshold voltage higher than zero. When the first conductivity type is N type and the second conductivity type is P type, the field-effect transistor forming the first differential pair has a threshold voltage equal to or higher than zero and the field-effect transistor forming the second differential pair has a threshold voltage lower than zero.

### Advantageous Effects of Invention

According to the present disclosure, in an operational amplifier supplied with first and second voltages to operate in the entire voltage range from the first voltage to the second voltage as an input and output range, differential amplification operation is performed for an input voltage in the entire voltage range by one of the first and second differential pairs selected depending on whether the input voltage is in a first voltage range or a second voltage range, and an active load common in the entire voltage range, whereby the amplification degree can be made constant in the entire voltage range.

### BRIEF DESCRIPTION OF DRAWINGS

FIG. 1 is a conceptual diagram illustrating a use example of an operational amplifier according to the present embodiment.

FIG. 2 is a block diagram illustrating a configuration example of the operational amplifier according to a first embodiment.

FIG. 3 is a circuit diagram illustrating a configuration example of the operational amplifier according to the first embodiment.

FIG. 4 is a first conceptual diagram showing the characteristics of transconductance for an input voltage input to the gate in each of an E-type NMOS transistor, a D-type NMOS transistor, and a native NMOS transistor that form a differential pair.

FIG. 5 is a second conceptual diagram showing the characteristics of transconductance for an input voltage input to the gate in each of an E-type NMOS transistor, a D-type NMOS transistor, and a native NMOS transistor that form a differential pair.

FIG. 6 is a circuit diagram illustrating a configuration example of the input voltage detection circuit shown in FIG. 1.

FIG. 7 is a circuit diagram illustrating a first example of the current supply shown in FIG. 6.

FIG. 8 is a circuit diagram illustrating a second example of the current supply shown in FIG. 6.

FIG. 9 is a circuit diagram illustrating a third example of the current supply shown in FIG. 6.

FIG. 10 is a circuit diagram illustrating a first example of the level shifter shown in FIG. 6.

FIG. 11 is a circuit diagram illustrating a second example of the level shifter shown in FIG. 6.

FIG. 12 is a circuit diagram illustrating a third example of the level shifter shown in FIG. 6.

FIG. 13 is a conceptual diagram illustrating a first configuration example of the input voltage detection circuit according to a second embodiment.

FIG. 14 is a circuit diagram illustrating a second configuration example of the input voltage detection circuit according to the second embodiment.

FIG. 15 is a waveform diagram illustrating a control example of first and second differential pairs according to the second embodiment.

### DESCRIPTION OF EMBODIMENTS

Embodiments of the present disclosure will be described in detail below with reference to the drawings. In the following, like or corresponding parts in the drawings are denoted by like reference signs and a description thereof is basically not repeated.

### First Embodiment

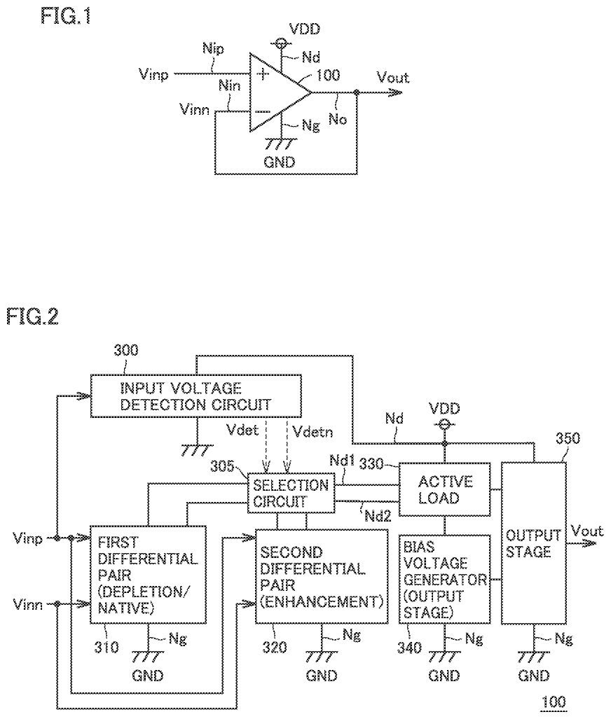

FIG. 1 is a conceptual diagram illustrating a use example of an operational amplifier according to the present embodiment.

Referring to FIG. 1, an operational amplifier 100 according to the present embodiment includes a noninverting input node Nip, an inverting input node Nin, and an output node No. In the following, the voltages at noninverting input node Nip and the inverting input node are referred to as input voltages Vinp and Vinn, and the voltage at output node No is referred to as output voltage Vout.

Operational amplifier 100 is connected to a ground node Ng to supply a ground voltage GND and a power supply node Nd to supply a power supply voltage VDD. In operational amplifier 100 receiving supply of ground voltage GND and power supply voltage VDD to operate, each of input voltages Vinp and Vinn and output voltage Vout changes in a voltage range of GND to VDD. That is, operational amplifier 100 operates as an operational amplifier with rail-to-rail input and output.

For example, operational amplifier 100 operates as a voltage follower amplifier in which output node No and inverting input node Nin are connected. In this configuration, when an output voltage Vsns from a not-shown sensor is input to noninverting input node Nip (Vinp=Vsns), impedance conversion is performed to obtain output voltage Vout equivalent to the sensor voltage (Vout=Vsns). It should be noted that operational amplifier 100 can be used in any manner different from voltage follower connection.

FIG. 2 is a block diagram illustrating a configuration example of the operational amplifier according to a first embodiment.

Referring to FIG. 2, operational amplifier 100 according to the first embodiment includes an input voltage detection circuit 300, a selection circuit 305, a first differential pair 310 and a second differential pair 320, an active load 330, a bias voltage generator 340 for output stage, and an output stage 350. As described below, active load 330 is formed with field-effect transistors of a first conductivity type. On the other hand, first differential pair 310 and second differential pair 320 are formed with field-effect transistors of a second conductivity type that is the conductivity type opposite to the first conductivity type.

Active load 330 is connected between differential nodes Nd1 and Nd2 and power supply node Nd. First differential pair 310 and second differential pair 320 are connected in parallel between differential nodes Nd1 and Nd2 and ground node Ng through selection circuit 305. Active load 330 is connected to both of first differential pair 310 and second differential pair 320 through differential nodes Nd1 and Nd2 and selection circuit 305. Input voltages Vinp and Vinn are input to each of first differential pair 310 and second differential pair 320 from noninverting input node Nip and inverting input node Nin.

In the present embodiment, power supply node Nd connected to active load 330 corresponds to an embodiment of “first power supply node”, and power supply voltage VDD corresponds to “first voltage”. On the other hand, ground node Ng connected to first differential pair 310 and second differential pair 320 corresponds to an embodiment of “second power supply node”, and ground voltage GND corresponds to “second voltage”.

Input voltage detection circuit 300 generates detection signals Vdet and Vdetn that are set to one of a logical high level (hereinafter simply referred to as “H level”) and a logical low level (hereinafter simply referred to as “L level”) in accordance with the level of input voltage Vinp.

As described later, detection signals Vdet and Vdetn are each complementarily set to one of H level and L level. Detection signals Vdet and Vdetn are input to selection circuit 305. In accordance with detection signals Vdet and Vdetn, selection circuit 305 electrically connects one of first differential pair 310 and second differential pair 320 to differential nodes Nd1 and Nd2 and electrically cuts off the other from differential nodes Nd1 and Nd2.

Active load 330 and bias voltage generator 340 for output stage are connected between power supply node Nd and ground node Ng. Output stage 350 is connected to power supply node Nd, ground node Ng, and output node No, as well as active load 330 and bias voltage generator 340. As described later, output stage 350 is configured to change output voltage Vo at output node No within a range of ground voltage GND to power supply voltage VDD, in accordance with the current difference between differential nodes Nd1 and Nd2.

Hereinafter, an example in which first differential pair 310 and second differential pair 320 are formed with N-type MOSFETs (which hereinafter may be simply referred to as “NMOS transistors”), and active load 330 is formed with P-type MOSFETs (which hereinafter may be simply referred to as “PMOS transistors”) will be described. That is, in the following example, P type corresponds to an embodiment of “first conductivity type”, and N type corresponds to an embodiment of “second conductivity type”.

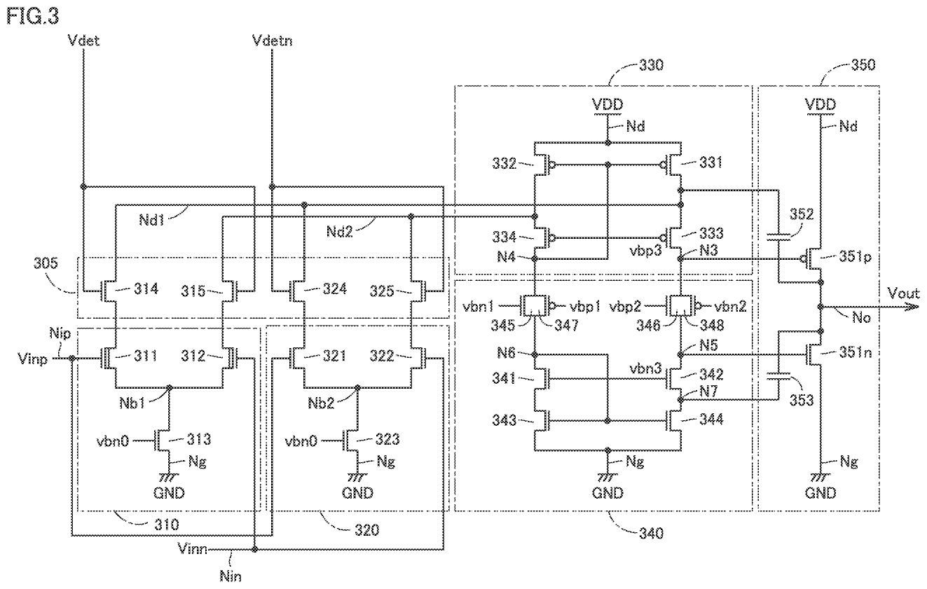

Referring to FIG. 3, a specific circuit configuration example of the operational amplifier shown in FIG. 2 will be described.

Referring to FIG. 3, first differential pair 310 includes NMOS transistors 311 and 312. NMOS transistors 311 and 312 are configured to have a threshold voltage Vt such that drain current flows when the gate-to-source voltage (which hereinafter may be simply referred to as “gate voltage”) is 0 [V]. For example, NMOS transistors 311 and 312 may be formed with depletion-type NMOS transistors or native NMOS transistors. Hereinafter, in order to collectively refer to NMOS transistors having a threshold voltage Vt≤0, a depletion-type NMOS transistor and a native NMOS transistor may be collectively referred to as (D/N) type NMOS transistor.

On the other hand, a common enhancement-type NMOS transistor with Vt>0 is basically simply referred to as “NMOS transistor” or may be referred to as E-type NMOS transistor in comparison with the (D/N) type. An enhancement-type PMOS transistor may also be simply referred to as PMOS transistor.

Selection circuit 305 includes NMOS transistors 314 and 315. (D/N)-type NMOS transistor 311 and NMOS transistor 314 are connected in series between differential node Nd1 and a node Nb1. Similarly, (D/N)-type NMOS transistor 312 and NMOS transistor 315 are connected in series between differential node Nd2 and node Nb1.

The gate of (D/N)-type NMOS transistor 311 is connected to noninverting input node Nip (input voltage Vinp), and the gate of (D/N)-type NMOS transistor 312 is connected to inverting input node Nin (input voltage Vinn). In first differential pair 310, (D/N)-type NMOS transistors 311 and 312 constitute a differential pair receiving input voltages Vinp and Vinn at the gates.

The gates of NMOS transistors 314 and 315 receive detection signal Vdet. Each of NMOS transistors 314 and 315 therefore operates as a selection switch that turns on when detection signal Vdet is H level and turns off when detection signal Vdet is L level.

NMOS transistor 313 is connected between node Nb1 and ground node Ng and receives a bias voltage vbn0 at the gate. NMOS transistor 313 operates as a bias tail current source for differential amplification to supply current in accordance with bias voltage vbn0.

Second differential pair 320 includes NMOS transistors 321 and 322. Selection circuit 305 further includes NMOS transistors 324 and 325. NMOS transistors 321 and 324 are connected in series between differential node Nd1 and a node Nb2. Similarly, NMOS transistors 322 and 325 are connected in series between differential node Nd2 and node Nb2.

The gate of NMOS transistor 321 is connected to noninverting input node Nip (input voltage Vinp), and the gate of NMOS transistor 322 is connected to inverting input node Nin (input voltage Vinn). In second differential pair 320, therefore, E-type NMOS transistors 321 and 322 constitute a differential pair receiving input voltages Vinp and Vinn at the gates.

The gates of NMOS transistors 324 and 325 receive detection signal Vdetn. Each of NMOS transistors 324 and 325 therefore operates as a selection switch that turns on when detection signal Vdetn is H level and turns off when detection signal Vdetn is L level.

NMOS transistor 323 is connected between node Nb2 and ground node Ng and receives bias voltage vbn0 at the gate. NMOS transistor 323 operates as a bias tail current source for differential amplification, in the same manner as NMOS transistor 313. Current of NMOS transistor 313 and current of NMOS transistor 323 are designed to be equivalent.

Active load 330 includes PMOS transistors 331 to 334. PMOS transistor 331 is connected between power supply node Nd and differential node Nd1. PMOS transistor 332 is connected between power supply node Nd and differential node Nd2. PMOS transistor 333 is connected between differential node Nd1 and a node N3, and PMOS transistor 334 is connected between differential node Nd2 and a node N4.

The gates of PMOS transistors 331 and 332 are connected to node N4. The gates of PMOS transistors 333 and 334 receive a common bias voltage vbp3. PMOS transistors 331 and 332 operate as active loads, and PMOS transistors 333 and 334 are cascoded to the active loads.

Bias voltage generator 340 includes NMOS transistors 341 to 346 and PMOS transistors 347 and 348. NMOS transistor 345 and PMOS transistor 347 are connected in parallel between node N4 and a node N6. NMOS transistors 341 and 343 are connected in series between node N6 and ground node Ng. Similarly, NMOS transistor 346 and PMOS transistor 348 are connected in parallel between node N3 and a node N5. NMOS transistors 342 and 344 are connected in series between node N5 and ground node Ng through a node N7.

The gate of NMOS transistor 345 receives a bias voltage vbn1, and the gate of NMOS transistor 346 receives a bias voltage vbn2. Similarly, the gate of PMOS transistor 347 receives a bias voltage vbp1, and the gate of NMOS transistor 348 receives a bias voltage vbp2. The gates of NMOS transistors 341 and 342 receive a bias voltage vbn3 in common. The gates of NMOS transistors 343 and 344 are connected to node N6.

In bias voltage generator 340, NMOS transistors 343 and 344 operate as active loads, and NMOS transistors 341 and 342 are cascoded to the active loads. Further, NMOS transistors 345 and 346 and PMOS transistors 347 and 348 operate as floating current sources.

Output stage 350 is configured as a push-pull type and includes a PMOS transistor 351p and an NMOS transistor 351n, and capacitors 352 and 353.

PMOS transistor 351p is connected between power supply node Nd and output node No. NMOS transistor 351n is connected between output node No and ground node Ng. The gate of PMOS transistor 351p is connected to node N3, and the gate of NMOS transistor 351n is connected to node N5.

NMOS transistor 351n operates to source current to output node No in response to current increase at differential node Nd1 in response to rise of input voltage Vinp. Conversely, PMOS transistor 351p operates to sink current from output node No in response to current increase at differential node Nd2 in response to fall of input voltage Vinp.

Bias voltage generator 340 can operate to apply a bias to the gate voltages of PMOS transistor 351p and NMOS transistor 351n so that class-AB amplification operation is performed. Specifically, class-AB operation is achieved by equalizing current of PMOS transistor 351p and NMOS transistor 351n with current flowing through NMOS transistors 313 and 323 (bias tail current source) in a period other than an amplification operation period, and controlling the bias voltage such that current a few hundreds to a few thousands of times larger than the current flows in the amplification operation. When class-AB amplification operation is unnecessary, for example, a current source or a current mirror circuit may be disposed simply, instead of bias voltage generator 340.

Capacitor 352 is connected between differential node Nd1 and output node No. Capacitor 353 is connected between output node No and node N7. Capacitors 352 and 353 operate as phase compensation capacitances.

Since detection signals Vdet and Vdetn are complementarily set to H level and L level, in selection circuit 305, one of NMOS transistor 314, 315 and NMOS transistor 324, 325 is selectively turned on and the other is turned off.

When Vdet=H level (Vdetn=L level) at which NMOS transistors 314 and 315 turn on, the differential pair of (D/N)-type NMOS transistors 311 and 312 is connected to differential nodes Nd1 and Nd2.

On the other hand, when Vdetn=H level (Vdetn=L level) at which NMOS transistors 324 and 325 turn on, the differential pair of E-type NMOS transistors 321 and 322 is connected to differential nodes Nd1 and Nd2.

In first differential pair 310, (D/N)-type NMOS transistors 311 and 312 correspond to “first field-effect transistor” and “second field-effect transistor”. NMOS transistors 314 and 315 form “first selection switch”, and NMOS transistor 313 forms “first current source transistor”.

In second differential pair 320, E-type NMOS transistors 321 and 322 correspond to “third field-effect transistor” and “fourth field-effect transistor”. NMOS transistors 324 and 325 form “second selection switch”, and NMOS transistor 323 forms “second current source transistor”.

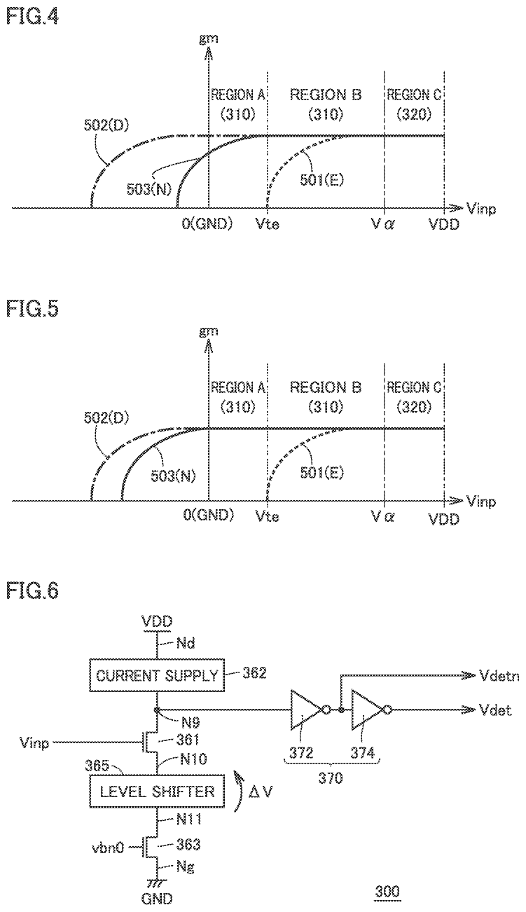

Referring now to FIG. 4 and FIG. 5, the voltage current characteristics of a depletion-type (D-type) NMOS transistor, a native NMOS transistor, and an enhancement-type (E-type) NMOS transistor will be described.

FIG. 4 and FIG. 5 show the characteristic line of transconductance for input voltage Vinp input to the gate in each of an E-type NMOS transistor, a D-type NMOS transistor, and a native NMOS transistor that form a differential pair. When a differential pair is formed with an NMOS transistor, input voltage Vinp corresponds to the gate-to-source voltage of the NMOS transistor. The unit of transconductance gm of the transistor shown in the vertical axis of FIG. 4 and FIG. 5 is [1/Ω], and drain current Id is 0 in the region of gm=0.

Referring to FIG. 4, in an E-type NMOS transistor, as indicated by characteristic line 501, gm=0 and current does not flow (Id=0) in a region in which input voltage Vinp is lower than input voltage Vte corresponding to threshold voltage Vt (Vt>0) of the E-type NMOS transistor. On the other hand, in a region Vinp>Vte, gm rises and Id>0, and when input voltage Vinp rises beyond a certain voltage, there is a region (saturation region) in which gm does not change with rise of input voltage Vinp. Therefore, second differential pair 320 of E-type NMOS transistors is unable to perform differential amplification in region A where 0<Vinp<Vte.

As indicated by characteristic line 502, a D-type NMOS transistor is a normally-on device in which threshold voltage Vt is a negative voltage and the saturation region is at Vinp=0. Therefore, in first differential pair 310 including D-type NMOS transistors, differential amplification operation can be performed even in an input voltage region (region A) of 0<Vinp<Vte.

Since fabrication of a depletion-type NMOS transistor may lead to cost increase, it is advantageous in terms of cost that first differential pair 310 is formed with native NMOS transistors obtained by fabricating NMOS on a P substrate.

As indicated by characteristic line 503, a native NMOS transistor has such characteristics that threshold voltage Vt is in the vicinity of 0 [V]. Therefore, differential amplification can be performed in the voltage region of 0<Vinp<Vte (region A) even when transistors 311 and 312 of first differential pair 310 are formed using native NMOS transistors having the characteristics of threshold voltage Vt<0.

In this way, in operational amplifier 100 shown in FIG. 1, differential amplification operation in region A (0<Vinp<Vte) can be performed by first differential pair 310 formed with D-type NMOS transistors or native NMOS transistors.

FIG. 5 shows another example of the characteristics of a native NMOS transistor. As indicated by characteristic line 503 in FIG. 5, a native NMOS transistor operating in the saturation region at gate voltage=0 [V] can also be fabricated, and it is understood that such native NMOS transistors are suitable for transistors 311 and 312 of first differential pair 310.

On the other hand, in a region in which input voltage Vinp is close to power supply voltage VDD, amplification operation is difficult for first differential pair 310 formed with D-type NMOS transistors or native NMOS transistors.

Referring to FIG. 3 again, when input voltage Vinp is in the vicinity of power supply voltage VDD in a state in which transistors 311 and 312 (D-type NMOS transistors or native NMOS transistors) forming first differential pair 310 are connected to differential nodes Nd1 and Nd2, the threshold voltage is 0 or negative and therefore the voltage at differential node Nd1 is also in the vicinity of power supply voltage VDD. As a result, Vds (drain-to-source voltage) of PMOS transistors 331 and 332 forming the active load is almost zero, and differential amplification operation is difficult.

By contrast, in NMOS transistors 321 and 322 (E type) forming second differential pair 320, when input voltage Vinp is in the vicinity of power supply voltage VDD, the voltage at differential node Nd1 is lower than power supply voltage VDD by the amount of threshold voltage Vt of the E-type NMOS transistor. As a result, a voltage corresponding in amount to threshold voltage Vt (for example, about 0.8 [V]) can be ensured as Vds of PMOS transistors 331 and 332 forming the active load, and differential amplification operation is possible.

Referring to FIG. 4 and FIG. 5 again, operational amplifier 100 according to the present embodiment performs differential amplification operation using second differential pair 320 formed with E-type NMOS transistors in a high voltage-side region C (Vinp>Vα). Specifically, in region C, detection signal Vdetn=H (Vdet=L) is set so that NMOS transistors 324 and 325 are turned on and NMOS transistors 314 and 315 are turned off. A boundary value Vα of region C can be set within a range of input voltage Vinp corresponding to the gate voltage range in which E-type NMOS transistors 321 and 322 operate in the saturation region.

In region B (Vte≤Vinp≤Vα), drain current is generated even in an E-type MOS transistor. Therefore, in region B, differential amplification is possible in both of first differential pair 310 ((D/N) type) and second differential pair 320 (E type). For this reason, in PTL 1, in an intermediate voltage region corresponding to region B, differential amplification is performed with bias current shared between the differential pair of E-type PMOS transistors and the differential pair of D-type PMOS transistors.

By contrast, in operational amplifier 100 according to the present embodiment, in both of region A and region B other than region C, differential amplification operation is performed using only first differential pair 310 of D-type NMOS transistors or native NMOS transistors. Specifically, in region A and region B, detection signal Vdet is set to H level (Vdetn=L) so that NMOS transistors 314 and 315 are turned on and NMOS transistors 324 and 325 are turned off. In this way, region A and region B form an embodiment of “first voltage range”, and region C forms an embodiment of “second voltage range”. It is understood that input voltage Vinp (Vinp=Vte) when the gate-to-source voltage of E-type NMOS transistors 321 and 322 is equal to threshold voltage Vt, that is, input voltage Vinp corresponding to threshold voltage Vt is included in “first voltage range”.

As an example, when power supply voltage VDD=5 [V] and ground voltage GND=0 [V], boundary value Vα can be set corresponding to Vinp=about 4 [V]. The boundary between region A and region B is typically a voltage in the neighborhood of Vinp=1 [V].

The configuration of the input voltage detection circuit for generating detection signals Vdet and Vdetn as described above will now be described.

FIG. 6 is a circuit diagram illustrating a configuration example of input voltage detection circuit 300.

Referring to FIG. 6, input voltage detection circuit 300 includes an NMOS transistor 361, a current supply 362, an NMOS transistor 363, a level shifter 365, and a buffer 370.

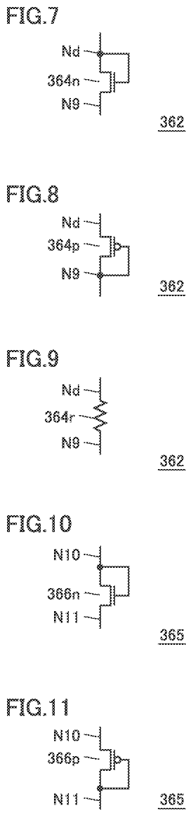

Current supply 362 is connected between power supply node Nd and node N9 to supply current from power supply node Nd to node N9. FIG. 7 to FIG. 9 show configuration examples of current supply 362. In a configuration example of FIG. 6, node N9 corresponds to an embodiment of “internal node”.

Referring to FIG. 7, current supply 362 can be formed with a diode-connected NMOS transistor 364n. Specifically, NMOS transistor 364n is connected between power supply node Nd and node N9 and has the gate connected to power supply node Nd.

Similarly, as shown in FIG. 8, current supply 362 may be formed with a diode-connected PMOS transistor 364p. Specifically, PMOS transistor 364p is connected between power supply node Nd and node N9 and has the gate connected to node N9.

Alternatively, as shown in FIG. 9, current supply 362 may be formed with a resistor element 364r connected between power supply node Nd and node N9.

Referring to FIG. 6 again, NMOS transistor 361 is connected between nodes N9 and N10. Level shifter 365 is connected between nodes N10 and N11. NMOS transistor 363 is connected between node N11 and ground node Ng.

NMOS transistor 363 receives bias voltage vbn0 at the gate and operates as a current source, in the same manner as NMOS transistor 323 in the second differential pair. NMOS transistor 363 forms “third current source transistor”.

Level shifter 365 is configured to produce a voltage drop ΔV with current by NMOS transistor 363. Thus, the source voltage of NMOS transistor 361 rises by ΔV compared with when level shifter 365 is not arranged.

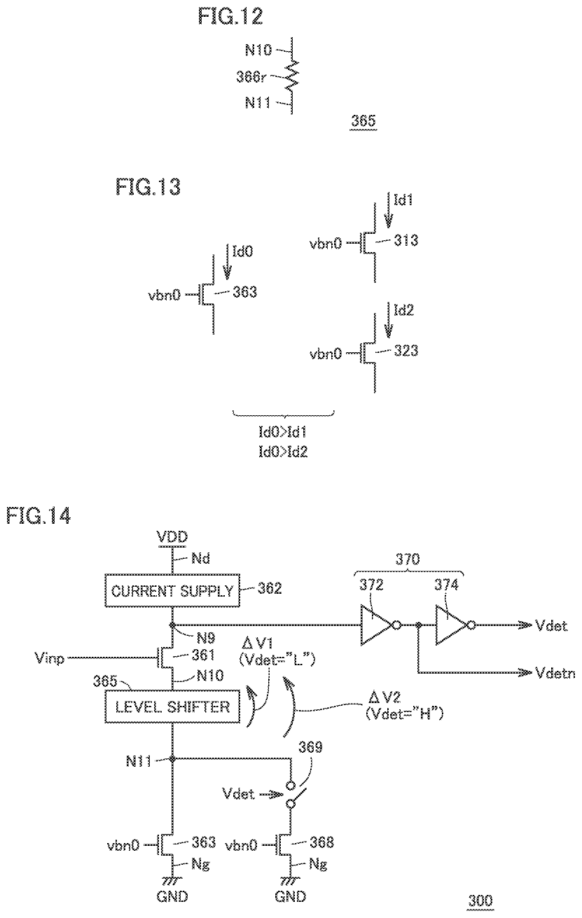

FIG. 10 to FIG. 12 show configuration examples of level shifter 365.

As shown in FIG. 10 to FIG. 12, level shifter 365 can be formed with a diode-connected NMOS transistor 366n, a diode-connected PMOS transistor 366p, or a resistor element 366r connected between node N11 and ground node Ng.

Referring to FIG. 6 again, buffer 370 includes inverters 372 and 374 connected in series. Inverter 372 generates detection signal Vdetn in accordance with a voltage at node N9. Specifically, inverter 372 sets detection signal Vdetn to H level when the voltage at node N9 is lower than a threshold voltage and sets detection signal Vdetn to L level when the voltage at node N9 is higher than a threshold voltage. Inverter 374 inverts the logical level of an output signal (detection signal Vdetn) of inverter 372 and outputs detection signal Vdet.

Therefore, when NMOS transistor 361 is off, node N9 is charged to the vicinity of power supply voltage VDD by current supply 362, and therefore detection signal Vdetn=L level and detection signal Vdet=H level. At this moment, in FIG. 3, since NMOS transistors 314 and 315 turn on and NMOS transistors 324 and 325 turn off, differential amplification operation is performed using the differential pair (first differential pair 310) of (D/N)-type NMOS transistors 311 and 312.

By contrast, when NMOS transistor 361 is on, the voltage at node N9 decreases, and therefore detection signal Vdetn=H level and detection signal Vdet=L level. At this moment, in FIG. 3, NMOS transistors 324 and 325 turn on (NMOS transistors 314 and 315 turn off), so that differential amplification operation is performed using the differential pair (second differential pair 320) of E-type NMOS transistors 321 and 322.

Specifically, it is understood that input voltage Vinp serving as the boundary value at which NMOS transistor 361 turns on corresponds to boundary value Vα between region B and region C shown in FIG. 4 and FIG. 5.

Here, NMOS transistor 361 is formed with an E-type NMOS transistor having the same characteristics (threshold voltage and transistor size, etc.) as E-type NMOS transistor 321 receiving input voltage Vinp at the gate in second differential pair (E type) 320. Therefore, NMOS transistor 361 corresponds to an embodiment of “replica transistor”.

When level shifter 365 is not arranged, NMOS transistor 361 is basically turned on or off in common with E-type NMOS transistor 321 of second differential pair 320. In this case, boundary value Vα corresponds to threshold voltage Vt (that is, Vte in FIG. 4 and FIG. 5) of NMOS transistor (E type) 361 and NMOS transistor (E type) 321. Therefore, even in a configuration not including level shifter 365, detection signal Vdetn can be generated such that second differential pair 320 (E type) is selected in conjunction with the operable range of E-type NMOS transistor 321.

When level shifter 365 is provided, the source voltage of NMOS transistor 361 is shifted toward power supply voltage VDD (that is, toward “first voltage”) by ΔV. Thus, NMOS transistor 361 is less likely to turn on than NMOS transistor 321, in response to the gate voltage (input voltage Vinp) common to NMOS transistors 361 and 321. Specifically, the level of input voltage Vinp at which NMOS transistor 361 turns on is raised by the amount of voltage drop ΔV in level shifter 365.

As a result, the boundary value Vα shown in FIG. 4 and FIG. 5 can be set to Vte+ΔV. Thus, even when the threshold voltage of E-type NMOS transistor 321 is lower than a design value due to manufacturing variations, second differential pair 320 (E type) can be used in a limited voltage region in which input voltage Vinp is higher than the threshold voltage of E-type NMOS transistor 321.

Further, second differential pair 320 (E type) may be used in a limited voltage region of input voltage Vinp in which E-type NMOS transistor 321 can operate in the saturation region, by setting ΔV as appropriate. In this way, with the provision of level shifter 365, second differential pair 320 (E type) can be used by limiting a more appropriate voltage range.

The provision of current supply 362 can prevent the source of NMOS transistor 361 from being directly connected to power supply node Nd. This can suppress turning-on of NMOS transistor 361 in response to input voltage Vinp in a voltage region lower than expected, specifically, a voltage region lower than the threshold voltage of E-type NMOS transistor 321, due to the channel length modulation effect.

As described above, in the operational amplifier according to the first embodiment, differential amplification operation can be performed in the input and output range entirely from ground voltage GND to power supply voltage VDD, by a combination of common active load 330 with one of first differential pair 310 ((D/N) type) and second differential pair 320 (E type) selected in accordance with the range of input voltage Vinp (region A to region C).

As a result, unlike PTL 1, there is no voltage region in which both of the differential pair of E-type NMOS transistors and the differential pair of D-type (or native) NMOS transistors perform differential amplification operation individually using part of bias current. Thus, the overall transconductance (gm) of the operational amplifier can be easily made constant in the entire voltage region (for example, between regions A to C in FIG. 4 and FIG. 5).

The overall amplification ratio Av (that is, amplification degree) in the differential amplification operation is expressed by the product of gm (transconductance) of the differential pair and a parallel connection resistance r0 (r0=rA//rD) of output resistance rA of the transistor forming the active load and output resistance rD of the transistor forming the differential pair (Av=gm·r0).

Here, output resistance rA corresponds to the output resistance of PMOS transistors 331 and 332 of active load 330. Output resistance rD corresponds to the output resistance of NMOS transistors 311, 312, 321, and 322 forming the differential pairs.

Here, it is known that drain current Id of an NMOS transistor in the saturation region is expressed by the following equation (1) using a gain coefficient β and a channel length modulation constant λ.

Id=(β/2)(Vgs−Vt)²·(1+λ·Vds) (1)

As indicated by the following equation (2), the gain coefficient β is an element constant determined by a surface average mobility μ, a channel length L, a channel width W, and a gate capacitance Cox per unit area. The channel length modulation constant λ is a constant by the shape effect of minute transistors and typically λ is about 0.1 to 0.01.

β=(W/L)·μ·Cox (2)

The output resistance r of an NMOS transistor is defined by r=(dId/dVds)⁻¹. Based on equation (1), dId/dVds can be obtained by the following equation (3).

dId/dVds=(β/2)·(Vgs−Vt)²·λ=(Id·λ)/(1+λ·Vds) (3)

Considering the typical value of λ, 1>>λ·Vds in equation (3) and dId/dVds≈1/(λ·Id). Therefore, the output resistance r of an NMOS transistor can be represented by λ·Id.

In the operational amplifier according to the present embodiment, common active load 330 (PMOS transistors 331 and 332) is used when differential amplification is performed by either of first differential pair 310 (D/N) and second differential pair 320 (E type). Further, the bias tail current of first differential pair 310 (current by NMOS transistor 313) and the bias tail current of second differential pair 320 (current by NMOS transistor 323) are equivalent.

Therefore, the bias tail current of first differential pair 310 in the differential amplification operation in region A and region B and the bias tail current of second differential pair 320 in the differential amplification operation in region C are equivalent. As a result, output resistance rD of the transistor forming the differential pair is kept at an equivalent value through region A to region C.

Similarly, current passing through active load 330 is also the same between differential amplification by first differential pair 310 and active load 330 (region A and region B) and differential amplification by second differential pair 320 and active load 330 (region C). As a result, output resistance rA of the transistor forming the active load is kept at an equivalent value through region A to region C. Accordingly, the above-noted parallel connection resistance r0 (r0=rA//rD) can be set to an equivalent value through region A to region C.

Further, gm of the differential pairs is determined by transistor size, tail current, mobility, and gate oxide film thickness, and the like of NMOS transistors 311, 312, 321, and 322 forming the differential pairs. For example, when gm of NMOS transistors 311 and 312 formed with native NMOS transistors is (1/M) times as large as gm of E-type NMOS transistors 321 and 322, the transistor size of NMOS transistors 311 and 312 is designed to be M times as large as the transistor size of E-type NMOS transistors 321 and 322 so that gm (transconductance) can be matched between first differential pair 310 and second differential pair 320. As a result, gm of the differential pairs that influences the overall amplification ratio Av can also made constant in each of region A to region C in the entire voltage range, by designing NMOS transistors 311, 312, 321, and 322 forming the differential pairs as appropriate.

In operational amplifier 100 according to the present embodiment, therefore, in the entire voltage range from ground voltage GND to power supply voltage VDD as the input and output range, the amplification degree (amplification ratio Av=gm·r0) in the entire voltage range can be made constant.

The amplification degree (amplification ratio Av=gm·r0) can be made constant in the entire voltage range by a method other than the method that matches both of gm (transconductance) and parallel connection resistance r0 between first differential pair 310 and second differential pair 320 described above. For example, the amplification degree (amplification ratio Av=gm·r0) in the differential amplification operation can be matched between first differential pair 310 and second differential pair 320 by adjusting and setting the ratio between the bias tail current of first differential pair 310 and the bias tail current of second differential pair 320 even when NMOS transistors 311 and 312 (first differential pair 310) and E-type NMOS transistors 321 and 322 (second differential pair 320) have an equivalent transistor size.

### Second Embodiment

In a second embodiment, improvement examples of the operational amplifier according to the first embodiment will be described.

FIG. 13 is a conceptual diagram illustrating a first configuration example of the input voltage detection circuit according to the second embodiment.

Referring to FIG. 13, in the first example of the second embodiment, supply current Id0 by NMOS transistor 363 (FIG. 6) of input voltage detection circuit 300 is set to be larger than supply current Id1 by NMOS transistor 313 (FIG. 3) of first differential pair 310 and supply current Id2 by NMOS transistor 323 (FIG. 3) of second differential pair 320.

For example, the transistor size (W/L ratio) of transistor 363 is set to be N times as large as the transistor size (W/L ratio) of each of transistors 313 and 323 so that supply current Id0 is N times as large as supply current Id1 and Id2 (N: a real number of N>1), thereby realizing Id0>Id1 and Id0>Id2. As described above, when the amplification degree (amplification ratio Av=gm·r0) is matched between first differential pair 310 and second differential pair 320 by the ratio of Id1 and Id2 (bias tail current), Id0=N1·Id1 and Id0=N2·Id2. That is, the current ratios N1 and N2 are both larger than 1.0 but not necessarily a common value.

Further, supply current Id0 can be set to be larger than supply currents Id1 and Id2 by making the transistor size of transistor 363 and the transistor size of each of transistors 313 and 323 equivalent and then setting the gate voltage (vbn0) of transistor 363 to be higher than the gate voltage (vbn0) of transistors 313 and 323. Even with this, the operation speed of input voltage detection circuit 300 can be made higher than the speed of differential amplification operation in first differential pair 310 and second differential pair 320.

As described above, in the present embodiment, first differential pair 310 and second differential pair 320 are selectively connected to active load 330 in accordance with the level of input voltage Vinp, thereby making the amplification degree constant in the entire voltage range. Therefore, if the operation speed of input voltage detection circuit 300 is lower than the operation speed of first differential pair 310 and second differential pair 320, the switching operation of first differential pair 310 and second differential pair 320, that is, the on-off switching of NMOS transistors 314 and 315 and NMOS transistors 324 and 325 may cause noise or distortion in differential amplification operation.

By contrast, as shown in FIG. 13, in input voltage detection circuit 300, supply current Id0 to NMOS transistor 361 is set to be larger than supply currents Id1 and Id2 to NMOS transistors 311, 312, 321, and 322 forming the differential pairs (N>1), whereby the operation speed of input voltage detection circuit 300 can be made higher than the speed of the differential amplification operation in first differential pair 310 and second differential pair 320. This can suppress noise or distortion in the differential amplification operation due to the switching operation of first differential pair 310 and second differential pair 320.

As described above, the supply current is set to be N times larger (N>1), whereby the operation speed of input voltage detection circuit 300 can be increased to √N times (in operation in a strong inversion saturation region) or N times (in operation in a weak inversion region) higher than the operation speed of first differential pair 310 and second differential pair 320. For example, the range of N≥10 is preferable.

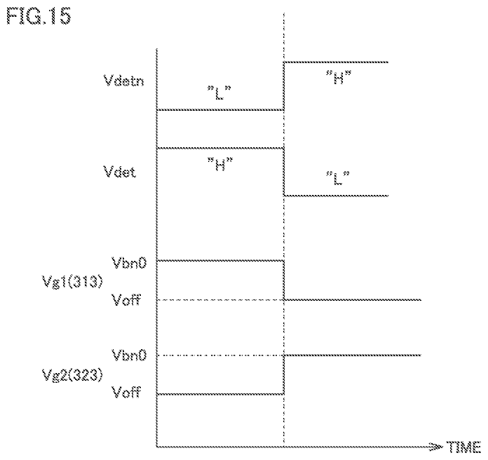

FIG. 14 is a circuit diagram illustrating a second configuration example of the input voltage detection circuit according to the second embodiment.

Referring to FIG. 14, input voltage detection circuit 300 according to the second example of the second embodiment differs from the configuration in the first embodiment (FIG. 6) in that it further includes an NMOS transistor 368 and a switch 369. NMOS transistor 368 and switch 369 are connected in series between node N11 and ground node Ng. NMOS transistor 368 receives bias voltage vbn0 at the gate and operates as a current source, in the same manner as NMOS transistor 363.

Switch 369 turns on and off in accordance with detection signal Vdet output by inverter 374. Specifically, switch 369 turns on when detection signal Vdet is H level and turns off when detection signal Vdet is L level. The configuration of the other part of input voltage detection circuit 300 shown in FIG. 14 is similar to that of FIG. 6, and a description of the part common to FIG. 6 will not be repeated.

In the configuration of FIG. 14, in an L level period of detection signal Vdet, the amount of voltage drop ΔV1 in level shifter 365 is produced by supply current only by NMOS transistor 363. By contrast, in an H level period of detection signal Vdet, the amount of voltage drop ΔV2 larger than ΔV1 is produced in level shifter 365 by the sum of supply currents by NMOS transistors 363 and 368 connected in parallel (ΔV2>ΔV1).

Therefore, with detection signal Vdet=H level (that is, Vinp<Vα), when input voltage Vinp becomes higher than Vte+ΔV2, that is, when input voltage Vinp exceeds Vte+ΔV2 and approaches power supply voltage VDD (first voltage), NMOS transistor 361 turns on to allow the detection signal to change from H level to L level.

By contrast, with detection signal Vdet=L level (that is, Vinp>Vα), when input voltage Vinp becomes lower than Vte+ΔV1, that is, when input voltage Vinp approaches ground voltage GND (second voltage) across Vte+ΔV1, NMOS transistor 361 turns off to allow the detection signal to change from L level to H level.

As a result, the boundary value Vα (first boundary value) when detection signal Vdet changes from H level to L level in response to rise of input voltage Vinp is equivalent to Vte+ΔV2. On the other hand, the boundary value Vα (second boundary value) when detection signal Vdet changes from L level to H level in response to fall of input voltage Vinp is equivalent to Vte+ΔV1. That is, the first boundary value can be set to be closer to power supply voltage VDD than the second boundary value.

Thus, when the level of detection signal Vdet, that is, the selection between first differential pair 310 and second differential pair 320 is switched in response to rise or fall of input voltage Vinp, a hysteresis can be applied to boundary value Vα (FIG. 4 and FIG. 5). As a result, excessive switching of selection between first differential pair 310 and second differential pair 320 in a short time (which is called chattering) can be suppressed.

FIG. 15 is a waveform diagram illustrating a control example of the first and second differential pairs according to the second embodiment. In the second embodiment, in first differential pair 310 and second differential pair 320 shown in FIG. 3, the gate voltages of NMOS transistors 313 and 323 operating as bias tail current sources are variably controlled.

Referring to FIG. 15, the gate voltages Vg1 and Vg2 of NMOS transistors 313 and 323 are controlled by one of bias voltage vbn0 (FIG. 3) for supplying an appropriate bias tail current and a voltage Voff for turning off NMOS transistors 313 and 323 (Id=0).

In a period of detection signal Vdet=H level, that is, in a period in which first differential pair 310 is selected, the gate voltage of NMOS transistor 313 (first differential pair 310) is set to Vg1=vbn0. On the other hand, the gate voltage of NMOS transistor 323 (second differential pair 320) is set to Vg2=Voff. Thus, in second differential pair 320 that does not perform differential amplification, NMOS transistor 323 is kept off.

On the other hand, in a period of detection signal Vdet=L level, that is, in a period in which second differential pair 320 is selected, the gate voltage of NMOS transistor 323 (second differential pair 320) is set to Vg2=vbn0. On the other hand, the gate voltage of NMOS transistor 313 (first differential pair 310) is set to Vg1=Voff. Thus, in first differential pair 310 that does not perform differential amplification, NMOS transistor 313 is kept off.

As a result, leak current in the differential pair not selected can be reduced by controlling first differential pair 310 and second differential pair 320 in accordance with FIG. 15. Thus, power consumption in operational amplifier 100 can be reduced.

The improvement examples illustrated in FIG. 13 to FIG. 15 can be combined as appropriate and applied to the operational amplifier according to the first embodiment.

In the present embodiment described above, an example in which active load 330 is formed with PMOS transistors and first differential pair 310 and second differential pair 320 are formed with D-type (or native) or E-type NMOS transistors, that is, a configuration example in which P type corresponds to “first conductivity type” and N type corresponds to “second conductivity type” has been described.

On the other hand, conversely, in the operational amplifier according to the present embodiment, active load 330 may be formed with NMOS transistors, first differential pair 310 may be formed with D-type (or native) PMOS transistors, and second differential pair 320 may be formed with E-type PMOS transistors. In this case, N type corresponds to an embodiment of “first conductivity type”, and P type corresponds to an embodiment of “second conductivity type”. In this case, the threshold voltage of a (D/N)-type PMOS transistor forming first differential pair 310 is Vt>0, and the threshold voltage of an E-type PMOS transistor forming second differential pair 320 is Vt<0.

In the configuration example in FIG. 3 and FIG. 6 (or FIG. 9), the conductivity type (N/P) of transistors may be interchanged as appropriate, and power supply node Nd (power supply voltage VDD) and ground node Ng (ground voltage) for first differential pair 310, second differential pair 320, and active load 330 may be interchanged to implement a similar circuit operation. That is, in this case, ground voltage GND corresponds to “first voltage” and ground node Ng corresponds to “first power supply node”. Power supply voltage VDD corresponds to “second voltage” and power supply node Nd corresponds to “second power supply node”.

Input voltage Vinp changes in a range of ground voltage GND (0 [V]) to power supply voltage VDD (for example, 5 [V]), whereas the gate-to-source voltage of a PMOS transistor forming a differential pair is (Vinp−VDD), and thus input voltage Vte corresponding to threshold voltage Vt (Vt<0) of the E-type PMOS transistor is represented by Vte=VDD+Vt. Therefore, the positions of region A and region C in FIG. 4 and FIG. 5 are switched, and first differential pair 310 of (D/N)-type PMOS transistors is selected in an input voltage range on the high voltage side (VDD side) of Vinp, while second differential pair 320 of E-type PMOS transistors is selected in an input voltage range on the low voltage side (GND side) of Vinp. With input voltage Vinp=Vte (for example, 4 [V]) when the gate-to-source voltage of the PMOS transistors forming the differential pair is the same as threshold voltage Vt, first differential pair 310 is selected. Further, boundary value Vα between region B and region C can be set corresponding to Vinp=about 1 [V].

N-type native transistors have preferable characteristics in terms of cost in that they can be fabricated without requiring an additional mask in fabrication of NMOS transistors on a P substrate commonly used. On the other hand, fabrication of P-type native transistors and D-type MOS transistors fabricated on an N substrate requires an additional mask in fabrication of E-type MOS transistors.

Therefore, in implementation of the operational amplifier according to the present embodiment, it is advantageous in terms of manufacturing cost to form a first differential pair with native NMOS transistors, form second differential pair 320 with E-type NMOS transistors, and form active load 330 with PMOS transistors.

Embodiments disclosed here should be understood as being illustrative rather than being limitative in all respects. The scope of the present disclosure is shown not in the foregoing description but in the claims, and it is intended that all modifications that come within the meaning and range of equivalence to the claims are embraced here.

### REFERENCE SIGNS LIST

100 operational amplifier, 300 input voltage detection circuit, 305 selection circuit, 310 first differential pair, 311, 312 NMOS transistor (depletion-type or native transistor), 313 to 315, 321 to 325, 331, 332, 341 to 346, 351n, 3631, 363, 364n, 366n, 368 NMOS transistor (enhancement type), 333, 334, 347, 348, 351p, 364p, 366p PMOS transistor, 320 second differential pair, 330 active load, 340 bias voltage generator, 350 output stage, 352, 353 capacitor, 362 current supply, 364r, 366r resistor element, 365 level shifter, 369 switch, 370 buffer, 372, 374 inverter, GND ground voltage, Id0 to Id2 supply current (current source transistor), N3 to N7, N9 to N11, Nb1, Nb2 node, Nd power supply node, Nd1, Nd2 differential node, Ng ground node, Nin inverting input node, Vinp, Vinn input voltage, Nip noninverting input node, No output node, Vα boundary value, vbn0 to vbn3, vbp1 to vbp3 bias voltage, VDD power supply voltage, Vdet, Vdetn detection signal, Voff off voltage, Vout output voltage.

1. An operational amplifier supplied with a first voltage and a second voltage to operate, comprising:
first and second input nodes to receive an input voltage;
an output node to output an output voltage;
first and second differential nodes;
an active load connected between a first power supply node to supply the first voltage and the first and second differential nodes, the active load being formed with a field-effect transistor of a first conductivity type;
a first differential pair connected between the first and second differential nodes and a second power supply node to supply the second voltage, the first differential pair producing a current difference between the first and second differential nodes in accordance with a voltage difference between the first and second input nodes and being formed with a field-effect transistor of a second conductivity type;
a second differential pair connected between the first and second differential nodes and the second power supply node in parallel with the first differential pair, the second differential pair producing a current difference between the first and second differential nodes in accordance with a voltage difference between the first and second input nodes and being formed with a field-effect transistor of the second conductivity type;
an input voltage detection circuit to generate a detection signal for selecting one of the first and second differential pairs in accordance with the input voltage;
an output stage to change a voltage at the output node in a range from the first voltage to the second voltage in accordance with a current difference between the first and second differential nodes; and
a selection circuit to electrically connect one of the first and second differential pairs to the first and second differential nodes and electrically cut off the other from the first and second differential nodes, in accordance with the detection signal, wherein
when the first conductivity type is P type and the second conductivity type is N type, the field-effect transistor forming the first differential pair has a threshold voltage equal to or lower than zero and the field-effect transistor forming the second differential pair has a threshold voltage higher than zero, and
when the first conductivity type is N type and the second conductivity type is P type, the field-effect transistor forming the first differential pair has a threshold voltage equal to or higher than zero and the field-effect transistor forming the second differential pair has a threshold voltage lower than zero.

2. The operational amplifier according to claim 1, wherein
the first differential pair includes
a first field-effect transistor of the second conductivity type electrically connected between the first differential node and the second power supply node and having a gate connected to the first input node, and
a second field-effect transistor of the second conductivity type electrically connected between the second differential node and the second power supply node and having a gate connected to the second input node,
the second differential pair includes
a third field-effect transistor of the second conductivity-type electrically connected between the first differential node and the second power supply node and having a gate connected to the first input node, and
a fourth field-effect transistor of the second conductivity type electrically connected between the second differential node and the second power supply node and having a gate connected to the second input node,
the selection circuit includes
a first selection switch connected between the first and second differential nodes and the second power supply node in series with the first and second field-effect transistors, and
a second selection switch connected between the first and second differential nodes and the second power supply node in series with the third and fourth field-effect transistors,
the first and second field-effect transistors have a first threshold voltage such that drain current is generated when the second voltage is input to the gate,
the third and fourth field-effect transistors have a second threshold voltage such that drain current is not generated when the second voltage is input to the gate,
the first and second selection switches are complementarily turned on and off in accordance with the detection signal,
the input voltage detection circuit generates the detection signal such that the first selection switch is turned on when the input voltage is within a first voltage range from the second voltage to a boundary value between the first and second voltages, and the second selection switch is turned on when the input voltage is within a second voltage range from the first voltage to the boundary value, and
the boundary value is set such that the first voltage range includes the input voltage corresponding to the second threshold voltage.

3. The operational amplifier according to claim 2, wherein
the input voltage detection circuit further includes
a current supply electrically connected between the first power supply node and an internal node,
a replica transistor electrically connected between the internal node and the second power supply node, fabricated to have same conductivity type and characteristics as the third field-effect transistor, and receiving, on its gate, the input voltage common to the third field-effect transistor and the replica transistor, and
a buffer to output the detection signal in accordance with a voltage level of the internal node, and
the buffer generates the detection signal such that the second selection switch is turned on when the replica transistor is on.

4. The operational amplifier according to claim 3, wherein
the input voltage detection circuit further includes
a level shifter connected between the replica transistor and the second power supply node, and
the level shifter shifts a source voltage of the replica transistor toward the first voltage.

5. The operational amplifier according to claim 2, wherein the boundary value is set such that the second voltage range falls within a range of the input voltage corresponding to a gate voltage range in which the third and fourth field-effect transistors operate in a saturation region.

6. The operational amplifier according to claim 2, wherein
during on of the first selection switch, when the input voltage approaches the first voltage across a first boundary value, the input voltage detection circuit switches on and off of the first and second selection switches such that the second selection switch turns on, and during on of the second selection switch, when the input voltage approaches the second voltage across a second boundary value, the input voltage detection circuit switches on and off of the first and second selection switches such that the first selection switch turns on, and
the first boundary value is set to be closer to the first voltage than the second boundary value.

7. The operational amplifier according to claim 3, or wherein
the first differential pair further includes
a first current source transistor connected between the first and second differential nodes and the second power supply node in series with the first and second field-effect transistors,
the second differential pair further includes
a second current source transistor connected between the first and second differential nodes and the second power supply node in series with the third and fourth field-effect transistors,
the input voltage detection circuit further includes
a third current source transistor connected between the second power supply node and the internal node in series with the replica transistor, and
supply current of the third current source transistor is larger than both of supply current of the first current source transistor and supply current of the second current source transistor.

8. The operational amplifier according to claim 7, wherein
the first current source transistor is fixed to an off state in an off period of the first selection switch, and
the second current source transistor is fixed to an off state in an off period of the second selection switch.

9. The operational amplifier according to claim 2, wherein
the first differential pair further includes
a first current source transistor connected between the first and second differential nodes and the second power supply node in series with the first and second field-effect transistors,
the second differential pair further includes
a second current source transistor connected between the first and second differential nodes and the second power supply node in series with the third and fourth field-effect transistors,
the first current source transistor is fixed to an off state in an off period of the first selection switch, and
the second current source transistor is fixed to an off state in an off period of the second selection switch.

10. The operational amplifier according to claim 1, wherein an operation speed of the input voltage detection circuit is higher than an operation speed of the first differential pair and the second differential pair.

11. The operational amplifier according to claim 1, wherein
the first voltage is higher than the second voltage, and
the first conductivity type is P type and the second conductivity type is N type.

12. The operational amplifier according to claim 1, wherein the field-effect transistor forming the first differential pair is a native transistor.
